(19) United States
(12) Patent Application Publication
(10) Pub. No.: US 2023/0136105 A1
(43) Pub. Date: May 4, 2023

(54) VERTICAL MECHANICAL STOPS TO PREVENT LARGE OUT-OF-PLANE DISPLACEMENTS OF A MICRO-MIRROR AND METHODS OF MANUFACTURE

(71) Applicant: CALIENT TECHNOLOGIES, INC., Goleta, CA (US)

(72) Inventor: Scott A. MILLER, Ithaca, NY (US)

(73) Assignee: CALIENT TECHNOLOGIES, INC., Goleta, CA (US)

(21) Appl. No.: 17/937,104

(22) Filed: Sep. 30, 2022

Related U.S. Application Data
(60) Provisional application No. 63/263,373, filed on Nov. 1, 2021.

(51) Int. Cl. B81B 3/00; G02B 17/00; G02B 7/182; G02B 26/08; B81C 1/00; G03F 7/00

(52) U.S. Cl. CPC B81B 3/0051; G02B 17/002; G02B 7/182; G02B 26/0833; B81C 1/00428; B81C 1/00531; G03F 7/0005; B81B 2201/045

(57) ABSTRACT

A mirror array includes a lid, a base, and a movable mirror between the lid and the base. The movable mirror includes a stationary frame including a cavity, a movable frame in the cavity, and a central stage in the cavity. The mirror array also includes a first protrusion on the base wafer. The first protrusion overlaps with the central stage in a first direction.

### CROSS REFERENCE TO RELATED APPLICATIONS

This application claims the benefit of U.S. Provisional Application No. 63/263,373, filed Nov. 1, 2021, entitled VERTICAL MECHANICAL STOPS TO PREVENT LARGE OUT-OF-PLANE DISPLACEMENTS OF A MICRO-MIRROR which application is incorporated herein in its entirety by reference.

### BACKGROUND

Technical Field: This disclosure relates to microelectromechanical systems (MEMS) mirror arrays and methods of manufacturing the MEMS mirror arrays that reduces and/or constrains out-of-plane displacements caused by shock.

Background: A MEMS (microelectromechanical systems) device is a micro-sized mechanical structure having electrical circuitry and is fabricated using conventional integrated circuit (IC) fabrication methods. One type of MEMS device is a microscopic gimbaled mirror device. A gimbaled mirror device includes a mirror component, which is suspended off a substrate, and is able to pivot about a gimbal due to electrostatic actuation. Electrostatic actuation creates an electric field that causes the mirror component to pivot. By allowing the mirror component to pivot, the mirror component is capable of having an angular range of motion in which the mirror component can redirect light beams to varying positions.

An optical switch is a switching device that couples light beams from an input fiber to an output fiber. Typically, the light beams from an input fiber are collimated and directed toward a desired location such as an output fiber. A movable mirror (e.g., a gimbaled mirror) in a switch mirror array redirects the light beams to desired locations.

Inside the optical switch, the mirrors in the array may need to rotate 10 — 20 degrees or more to direct the light beams to the desired locations. The mirrors need sufficient space above and below to allow these rotations. However, having this much space above and below the mirrors allows the mirrors to also move linearly in the vertical (out-of-plane) direction. The mirror flexures are designed to prevent this undesired linear, out-of-plane motion under normal operating conditions. When the optical switch is being handled during shipment or installation, for example, the optical switch could be dropped or impacted with sufficient force to cause the mirrors to undergo large out-of-plane deflections. This may damage mirrors in the switch array resulting in them being inoperable.

What is needed are MEMS mirror arrays and methods of manufacturing the MEMS mirror arrays that reduces and/or constrains out-of-plane displacements caused by shock.

### SUMMARY

Disclosed are MEMS mirror arrays and methods of manufacturing the MEMS arrays that constrains out-of-plane displacement caused by shock which reduces the likelihood of damage. Also disclosed are MEMS mirror arrays and methods of manufacturing the arrays that constrains out-of-plane displacements while still allowing large angular rotations needed for optical switching.

One aspect of the disclosure provides a mirror array. The mirror array includes a lid, a base, and a movable mirror between the lid and the base. The movable mirror includes a stationary frame including a cavity, a movable frame in the cavity, and a central stage in the cavity. The mirror array also includes a first protrusion on the base. The first protrusion overlaps with the central stage in a first direction.

Implementations of the disclosure may include one or more of the following optional features. The central stage can include a bottom portion facing the first protrusion. Additionally, the first protrusion can be spaced apart from the bottom portion of the central stage by a predetermined distance. The predetermined distance between the first protrusion and the bottom portion of the central stage is between 3 μm and 15 μm.

Optionally, the mirror array further may include a second protrusion on the lid and a third protrusion on the lid. The second protrusion and the third protrusion can be configured to extend towards the base. The mirror array can also include a first stationary frame flexure and a second stationary frame flexure. The first stationary frame flexure and the second stationary frame flexure suspend the movable frame from the stationary frame. The second protrusion can be configured to overlap with the first stationary frame flexure in the first direction, and the third protrusion can be also configured to overlap with the second stationary frame flexure in the first direction. The second protrusion can also be positioned apart from the first stationary frame flexure by a predetermined distance. The predetermined distance between the second protrusion and the first stationary frame flexure is between 3 μm and 15 μm. The third protrusion can also be positioned apart from the second stationary frame flexure by a predetermined distance. The predetermined distance between the third protrusion and the secondary stationary frame flexure is also between 3 μm and 15 μm. The second protrusion and the third protrusion can be positioned so that the second protrusion and the third protrusion are non-overlapped with the central stage in the first direction.

The mirror array is further configurable to include a fourth protrusion on the base and a fifth protrusion on the base. The first protrusion can be positioned between the fourth protrusion and the fifth protrusion. Additionally, the fourth protrusion can be configured to support a first support member, while the fifth protrusion is configured to support a second support member. The central stage can also include a bottom portion extending towards the first protrusion, wherein the bottom portion is positioned between the first support member and the second support member.

Another aspect of the disclosure provides a mirror array. The mirror array includes a movable mirror and a lid wafer covering the movable mirror. The movable mirror also includes a stationary frame including a cavity, a movable frame in the cavity, and a central stage in the cavity. The movable frame can be suspended from the stationary frame by a first stationary frame flexure and a second stationary frame flexure. The mirror array can also include a first protrusion on the lid wafer. The first protrusion is extended towards the movable mirror.

Implementations of the disclosure may include one or more of the following optional features. The first protrusion can overlap with the first stationary frame flexure in a first direction. A gap can be provided between the first protrusion and the first stationary frame flexure that is between 3 μm and 15 μm. The mirror array can further include a second protrusion on the lid wafer. The second protrusion can be positioned to overlap with the second stationary frame flexure in the first direction. A gap can be provided between the second protrusion and the second stationary frame flexure that is between 3 μm and 15 μm.

The mirror array is further configurable to include a base wafer and a third protrusion on the base wafer. The third protrusion can also overlap with the central stage in the first direction. The third protrusion can also be spaced apart from a bottom portion of the central stage by a predetermined distance, such as 3 μm and 15 μm.

Both the foregoing general description and the following detailed description are exemplary and explanatory only and are not restrictive of the disclosed embodiments, as claimed.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

U.S. Pat. No. 5,501,893 A issued Mar. 26, 1996 to Laermer et al.;

U.S. Pat. No. 5,635,739 A issued Jun. 3, 1997 to Grieff et al.;

U.S. Pat. No. 5,696,619 A issued Dec. 9, 1997 to Knipe et al.;

U.S Pat. No. 6,430,333 B1 issued Aug. 6, 2002 to Little et al.;

U.S Pat. No. 6,664,706 B1 issued Dec. 16, 2003 to Hung et al.;

U.S Pat. No. 6,914,711B2 issued Jul. 5, 2005 to Novotny et al.;

U.S. Pat. No. 7,092,141 B2 issued Aug. 15, 2006 to Kim et al.;

U.S. Pat. No. 7,261,826 B2 issued Aug. 28, 2007 to Adams et al.;

U.S. Pat. No. 7,330,297 B2 issued Feb. 12, 2008 to Noh et al. and

BEHIN, et al., Magnetically Actuated Micromirrors for FiberOptic Switching, 1998, Dec. 31.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1 illustrates a MEMS mirror array including a plurality of movable mirrors;

FIG. 2 illustrates the wafer after a release etch separates portions of the structure and after the attachment of the lid wafer;

FIGS. 3A-B illustrates a maximum out-of-plane deflection of a top surface vs. rotation angles (FIG. 3A) and a minimum out-of-plane deflection of a bottom surface vs. rotation angles (FIG. 3B);

FIG. 4 illustrates a partial cross-section of a mirror array;

FIG. 5 illustrates a partial cross-section of a mirror array with mechanical stops;

FIG. 6 illustrates a movable mirror with a base mechanical stop location identified;

FIGS. 7A-H illustrates a process for fabricating a base wafer;

FIG. 8 illustrates a partial cross-section of a mirror array with a base wafer and a lid wafer;

FIG. 9 illustrates a movable mirror with an indication of locations for mechanical stops; and

FIGS. 10A-I illustrates a process for fabricating the lid wafer.

### DETAILED DESCRIPTION

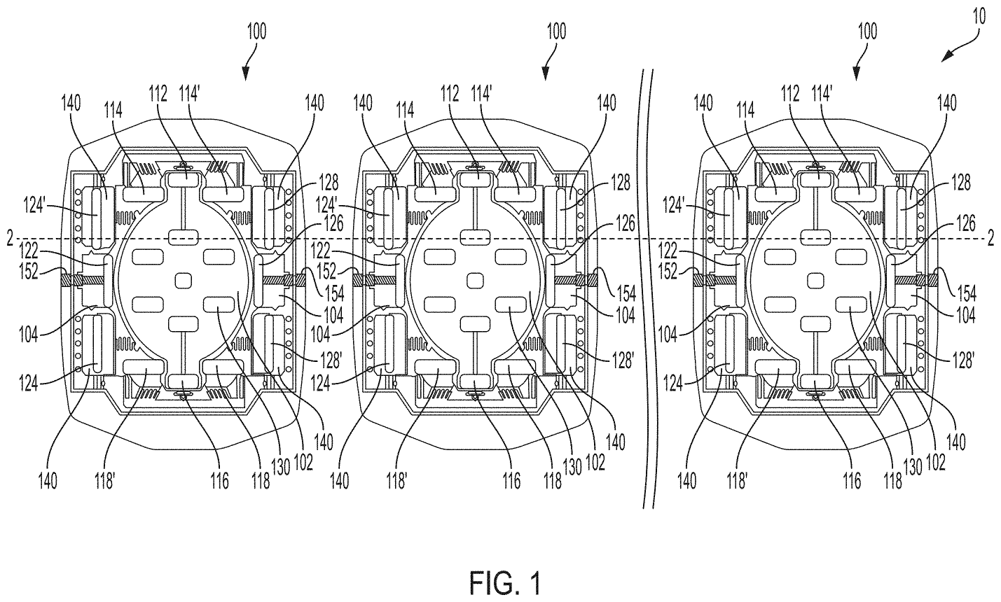

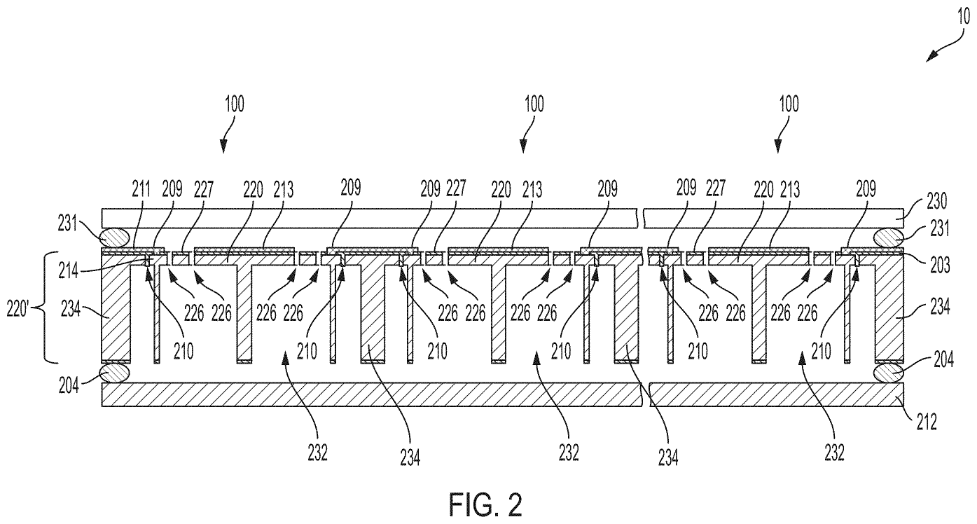

FIG. 1 illustrates a partial MEMS mirror array 10 including a plurality of MEMS mirrors 100 (also referred as actuators). At each end of a stage or frame, actuator 100 uses a single movable blade, with two corresponding fixed blades as an actuation mechanism structure to enable rotation. Actuator 100 uses two such actuation mechanism structures per stage and two such actuation mechanism structures per frame. A plurality of blades are provided. A first blade 112 is coupled to stage 102 (central stage 220 in FIGS. 2, 4, 5, and 8) and is flanked on either side by a pair of first flanking blades 114, 114′ which are coupled to moveable frame 104 (moveable frame 227 in FIGS. 2, 4, 5, and 8) on opposite ends of first blade 112. Stage 102 is pivotally coupled to moveable frame 104 such that first blade 112 is configured to move relative to first flanking blades 114, 114′. When a potential difference is applied between first blade 112 and one of the first flanking blades 114, 114′, an attraction is generated between the blades causing stage 102 to pivot. For example, first blade 112 may be held at a ground potential while an active voltage is applied to either of the first flanking blades 114, 114′. The application of an active voltage to first flanking blade 114, for example, will attract the first blade 112, thereby causing stage 102 to rotate or pivot in a corresponding direction. Similarly, the application of an active voltage to first flanking blade 114′ will attract first blade 112 and cause stage 102 to rotate or pivot in an opposite direction to that resulting from the attraction to first flanking blades 114.

A second blade 116 is coupled on end of stage 102 opposite the location of the first blade 112, with a pair of second flanking blades 118, 118′ coupled to moveable frame 104 on opposite ends of second blade 116. Second blade 116 moves relative to second flanking blades 118, 118′. In order to provide the desired motion of stage 102 and to resist unwanted rotations, actuation voltages are applied concurrently with respect to first blade 112 and second blade 116. For example, the range of motion for the stage 102 is between +15 degrees and −15 degrees, approximately. When the potential difference is applied between the second blade 116 and one of second flanking blades 118, 118′, an attraction is generated between the blades resulting in the rotation of stage 102 in a manner similar to that discussed above with respect to the first blade 112. The use of actuation mechanisms in tandem on each end of stage 102 minimizes or reduces undesired twisting of the stage 102 to provide for more uniform rotation.

A similar actuation mechanism structure may be used for rotation of moveable frame 104. For example, a first side blade 122 is coupled to moveable frame 104 and first side flanking blades 124, 124′are coupled to stationary frame 140 (stationary frame 214 in FIGS. 2, 4, 5, and 8) on opposite ends of first side blade 122.

Moveable frame 104 is pivotally coupled to the stationary frame 140 such that first side blade 122 is configured to move relative to first side flanking blades 124, 124′. When a potential difference is applied between the first side blade 122 and one of the first side flanking blades 124, 124′, an attraction is generated between the blades causing moveable frame 104 to pivot in a manner similar to that discussed above in relation to stage 102. As shown, the moveable frame 104 is suspended from the stationary frame 140 by mirror flexure 152 (e.g., spring, first stationary frame flexure) and a second mirror flexure 154 (e.g., spring, second stationary frame flexure).

Second side blade 126 is coupled on the opposite end of moveable frame 104, with second side flanking blades 128, 128′ coupled to stationary frame 140 on opposite ends of second side blade 126. Second side blade 126 moves relative to second side flanking blades 128, 128′. When the potential difference is applied between second side blade 126 and one of second side flanking blades 128, 128′, an attraction is generated between the blades facilitating the rotation of moveable frame 104. The use of actuation mechanisms in tandem on each end of moveable frame 104 minimizes or reduces undesired twisting of the frame to provide for more uniform rotation. For example, the range of motion for the movable frame 104 is between +20 degrees and −20 degrees, approximately.

Alternatively, a stage 102 or moveable frame 104 may only have an actuation mechanism structure on a single end. For another embodiment, actuator 100 may have other actuation mechanism structures without departing from the scope of the disclosure.

For one embodiment, a plurality of elongated members 130 can be provided (e.g., elongated member 130) which are coupled to the undersurface of stage 102 to stiffen the stage 102 and minimize or reduce top surface distortions. In addition, the elongated members 130 on stage 102 may be used to remove etch depth variations across the device. Elongated member 130 may be constructed similar to that of blades discussed herein. FIG. 1 illustrates seven elongated members 130 where six of the elongated members have substantially the same length and are positioned off-center on the stage 102, and the seventh elongated member 130 has a shorter length and is positioned centrally on the stage 102. For example, the seventh elongated member 130 is approximately 10% to 75% shorter than other elongated members 130 (that are positioned “off-center”).

For one embodiment, actuator 100 may be fabricated on a wafer level using semiconductor fabrication techniques, as discussed below. For such an embodiment, stationary frame 140 may be formed from a substrate, for example, constructed from silicon. Where all blades are directly driven by different control voltages, actuator 100 may use four voltages, plus a ground. With this arrangement, the number of conductive paths on a substrate quickly becomes very large as multiple actuators are combined to form an array. The low voltages required by the blade actuators discussed herein may allow for control circuitry to be fabricated into the substrate so that only control signals need be routed, rather than separate lines for each blade. This results in a significant reduction in lead count. Lower voltages may also reduce the necessity for spacing between leads to avoid arcing and cross-talk.

FIG. 2 illustrates a partial cross-section of the mirror array 10 illustrated in FIG. 1 along the lines 2-2 which illustrates a final structure release on the wafer topside using dry etching, which punctures through trenches 226 to suspend movable elements of the mirror 213 and the frame 227 (also referred as movable frame). In addition, the release etch promotes electrical isolation by separating, for example, the silicon of the frame 227 from the silicon of central stage 220 and stationary frame 214. The vias 209 serve to connect the regions of silicon to the metal interconnects 211. To completely seal the mirrors 213 from the outside environment, a lid wafer 230 is bonded to the device wafer 220′, preferably through the frit glass seal 231. The lid wafer 230 is typically glass to allow incoming light to be transmitted with low loss in the mirror cavity 232, reflect off of the surface of the mirror surface, and transmit out of the mirror cavity 232.

The trenches 210 are filled with a dielectric material, which for one embodiment is silicon dioxide. The filled trenches 210 provide the electrical isolation between blades after the mirror is released. A dielectric layer 203 also remains on the surface of the device wafer 220′ and is planarized after the fill process to ease subsequent lithographic patterning and eliminate surface discontinuities. Structure release is accomplished at the upper surface (topside) of the device wafer 220′ using dry etching, which punctures through a plurality of trenches 226 to suspend the movable elements of the mirror 213 and the frame 227. Support webbing 234 (also referred as support member) is also provided. As shown, the bottom portion of the central stage 220 is between the support webbings 234. A base wafer 212 is bonded to the device wafer 220′ to protect the blades after release. A hermetic seal 204 can surround the entire mirror array. The hermetic seal 204 can be formed by the frit material between the base wafer 212 and the device wafer 220′.

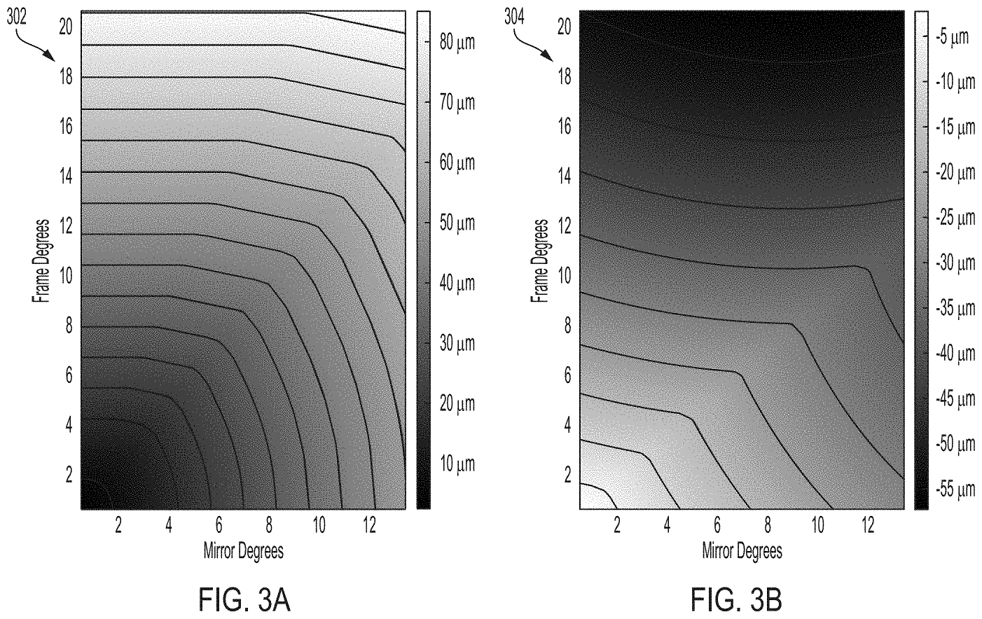

FIGS. 3A-B illustrates a maximum out-of-plane deflection of a top surface (of mirror 213) vs. rotation angles 302 and a minimum out-of-plane deflection of a bottom surface (of the central stage 220) vs. rotation angles 304. The maximum out-of-plane deflection in FIG. 3A reflects frame degrees from 0-20 on a y-axis and mirror degrees of 0-14 in an x-axis. The values range from 0 μm to 85 μm, with the lowest values being closest to the area around 0 frame degrees and 0 mirror degrees and the high values being from about 19-20 frame degrees and 0-14 mirror degrees. The minimum out-of-plane deflection of a bottom surface vs. rotation angles in FIG. 3B reflects frame degrees from 0-20 on a y-axis and mirror degrees of 0-14 in an x-axis. The values range from −60 μm to 0 μm, with the highest values being closest to the area around 0 frame degrees and 0 mirror degrees and the lowest values being from about 19-20 frame degrees and 0-14 mirror degrees.

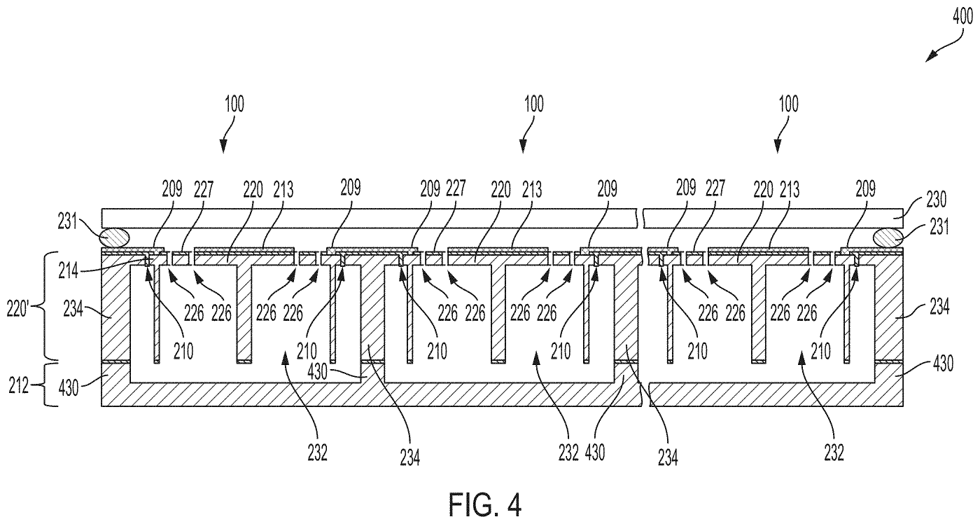

FIG. 4 illustrates a partial cross-section of a mirror array 400 with support anchors 430. As shown, the base wafer 212 includes the support anchors 430. The support anchors 430 (also referred as protrusions or base protrusions) are positioned below the support webbings 234. Accordingly, each of the support anchors 430 of the base wafer 212 overlaps with a corresponding support webbing 234 in a first direction (e.g., vertical direction). As a result, the support anchors 430 support the support webbings 234. As shown, the support anchors 430 also support the device wafer 220′. The base wafer 212 is bonded to the support anchors 430 via thermal compression, eutectic, or fusion bonding. As a result, the base wafer 212 is bonded to the device wafer 220′.

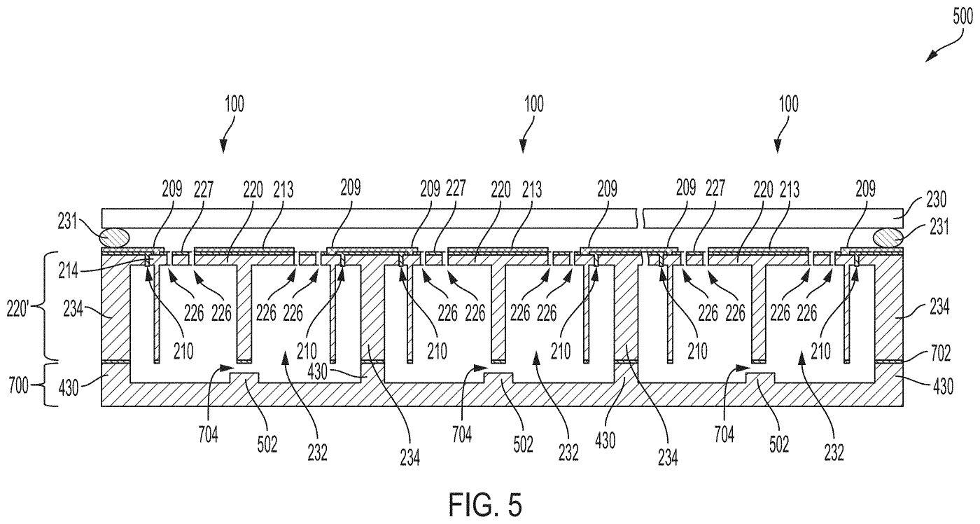

FIG. 5 illustrates a partial cross-section of a mirror array 500 with mechanical stops 502 (also referred as protrusions or base protrusions) on a base wafer 700 (e.g., silicon wafer, substrate). As shown, each of the mechanical stops 502 overlaps with a corresponding central stage 220/mirror 213 in the first direction. As shown, each of the central stages 220 has a bottom portion facing a corresponding mechanical stop 502. A gap 704 is provided between the bottom of the device wafer 220′ (base or bottom portion of the central stage 220) and the top surface of the mechanical stop 502. As shown, the mechanical stop 502 is between the support anchors 430.

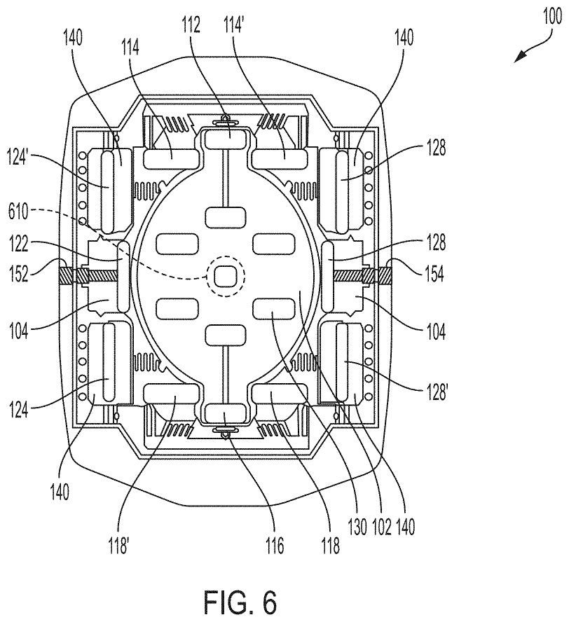

FIG. 6 illustrates a central stage 102 (central stage 220 in FIGS. 2, 4, 5, and 8), which supports a mirror 213, with a location 610 for the mechanical stop 502 of FIG. 5. For example, the mechanical stops 502 can be located directly under the center of each mirror 213/central stage 220. The gap 704 between the bottom of the center loading structure of the mirror 213 (base or bottom portion of the central stage 220) and the mechanical stop 502 can be between 3 μm and 15 μm.

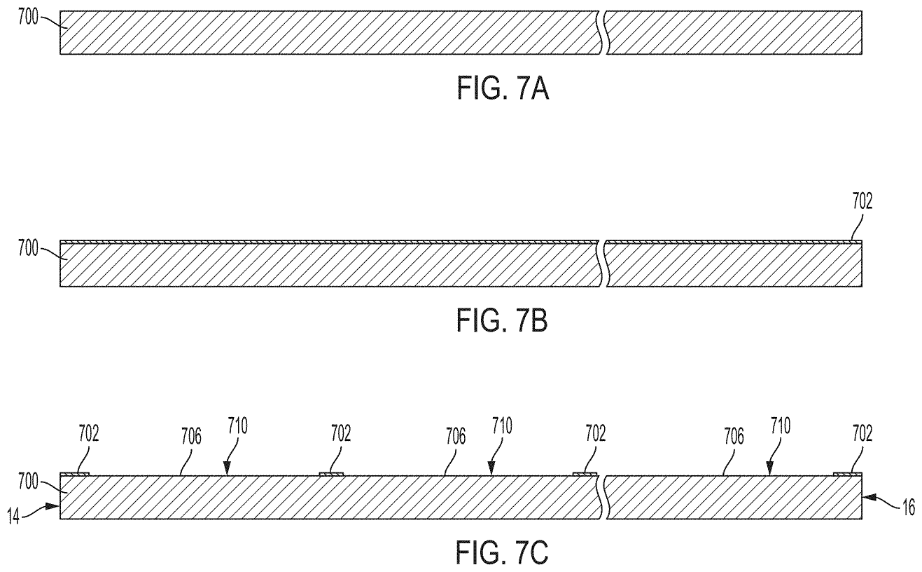

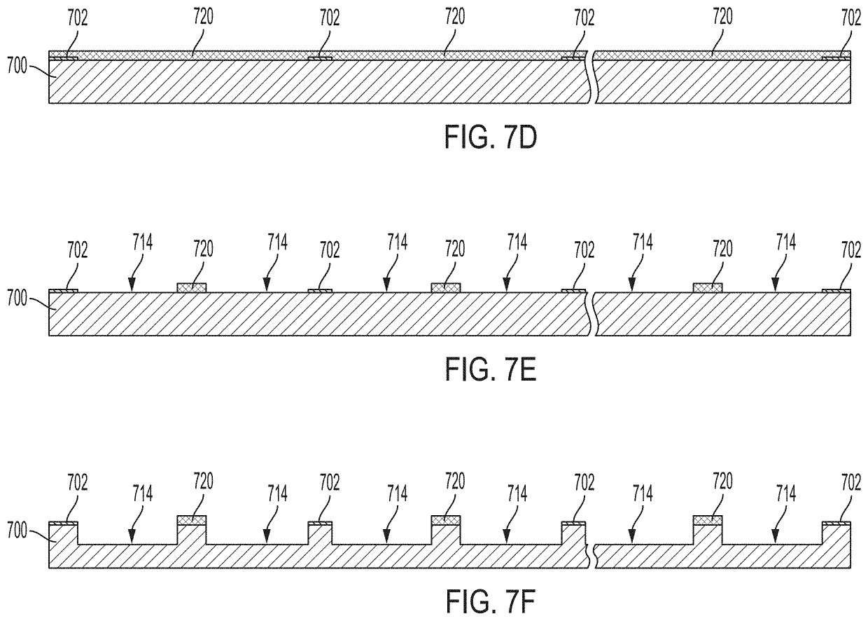

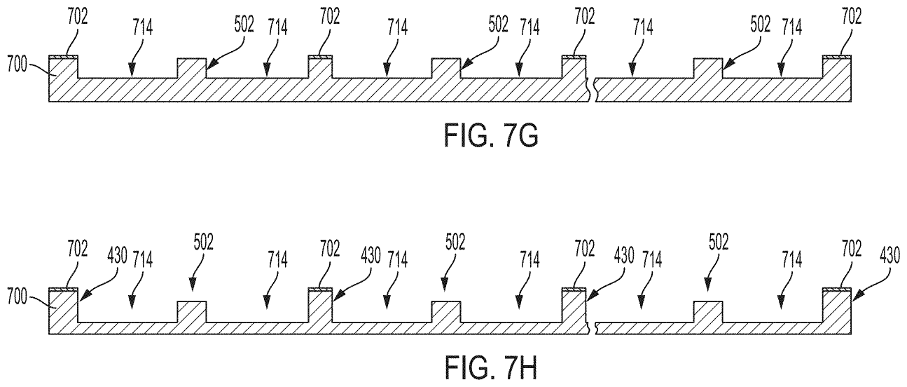

FIGS. 7A-H illustrates a process for fabricating a base wafer 700. A base wafer 700 is shown in FIG. 7A. A hard mask layer 702 is deposited on the base wafer 700 as shown in FIG. 7B. The hard mask layer 702 can be silicon dioxide, silicon nitride, aluminum, or another material that can serve as a mask for deep reactive ion etching of silicon. The hard mask layer 702 can also serve as the bonding material later in the process. Turning to FIG. 7C, hard mask layer 702 is patterned to allow for the etching of the cavity below the mirror 213. The patterning results in the hard mask layer 702 having spaces 706 between a first end of the silicon wafer 14 and a second end of the silicon wafer 16. The spaces 706 expose top surfaces 710 of the base wafer 700. The patterning is done using standard photolithography and etching methods.

A coating of photoresist material 720 (also referred as photoresist layer) is deposited on the hard mask layer 702 and the base wafer 700 as shown in FIG. 7D. The photoresist material 720 is patterned as shown in FIG. 7E to define the locations of the mechanical stop 502 in FIG. 5. In FIG. 7F, deep reactive ion etching is used to partially etch into the base wafer 700. As a result, the deep reactive ion etching etches exposed surfaces 714 of base wafer 700. The depth of this etch can be determined by the final desired depth of the cavity minus the gap desired between each of the mechanical stops 502 and the bottom of the center loading structure on a corresponding mirror 213. For example, the final desired depth of the cavity is equal or greater than 55 μm and less than the thickness of the base wafer 700. The photoresist material 720 is stripped from the silicon wafer 700 as shown in FIG. 7G to start forming the gaps 704. Deep reactive ion etching is then used to complete the etching of the cavity to a final desired depth as shown in FIG. 7H. As shown in FIG. 7H, during the deep reactive ion etching process, top surfaces of the mechanical stops 502 are also etched. Accordingly, the height for each of the mechanical stops 502 is adjusted to a final desired height. As a result, the gap 704 (e.g., gap between 3 μm and 15 μm) is formed between each of the mechanical stops 502 and the bottom of the center loading structure on the corresponding mirror 213 (base or bottom portion of the central stages 220). Un-etched portions of the base wafer 700 covered by the hard mask layer 702 are the support anchors 430. The hard mask layer 702 can remain on the base wafer 700 or be removed, depending on the bonding technique.

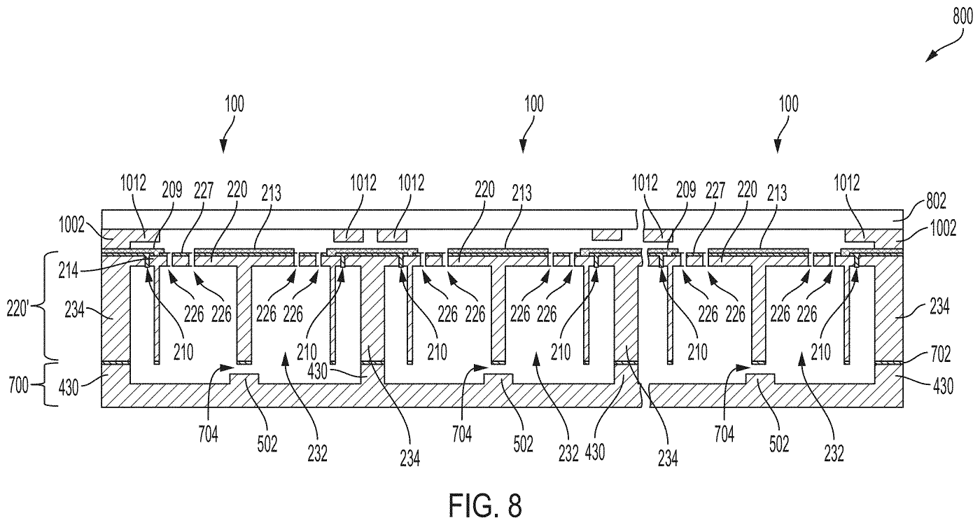

FIG. 8 illustrates a partial cross-section of a mirror array 800 with a base wafer 700 and a lid wafer 802 (e.g., glass wafer). Mechanical stops 502 prevent a large downward out-of-plane deflection of the mirrors 213 and are fabricated on the base wafer 700 as described above. In addition, mechanical stops 1012 (also referred as protrusions or lid protrusions) to prevent large upward out-of-plane deflections are fabricated on the lid wafer 802.

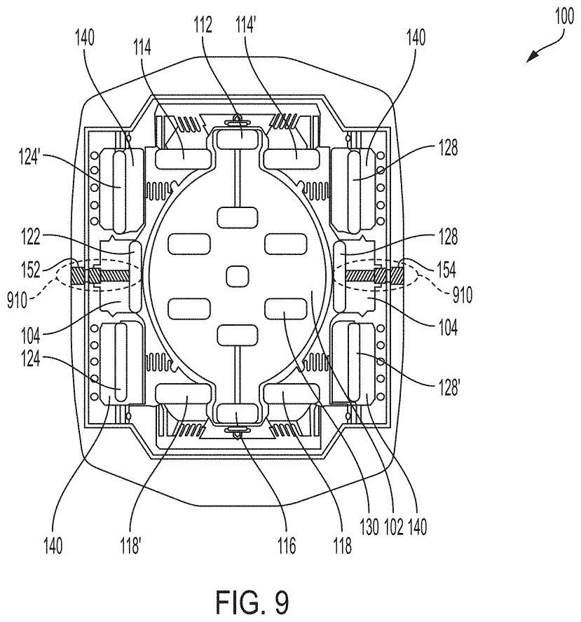

FIG. 9 illustrates an indication of locations 910 for mechanical stops 1012. The mechanical stops 1012 can be located directly above the center of each mirror's flexures 152, 154 (also referred as stationary frame flexures) as shown in FIG. 9. In other words, each of the mechanical stops 1012 may overlap with a corresponding mirror's flexure 152, 154 in the first direction. Special care should be taken in the location of these mechanical stops 1012 to ensure that the mechanical stops 1012 will not block the light reflected from the mirrors 213 (e.g., mechanical stops 1012 non-overlapping with the mirrors 213/central stages 220). A gap between the top of the mirror flexures 152, 154 and the mechanical stop 1012 can be between 3 μm−15 μm.

As shown in FIGS. 8 and 9, one aspect of the disclosure provides the mirror array 800. As shown, the mirror array 800 includes a lid (lid wafer 802), a base (base wafer 700), and a movable mirror 100 between the lid (lid wafer 802) and the base (base wafer 700). The movable mirror 100 includes a stationary frame 214 including a cavity 232, a movable frame 227 in the cavity 232, and a central stage 220 in the cavity 232. As shown, the mirror array 800 also includes a first protrusion (mechanical stop 502) on the base (base wafer 700). The first protrusion (mechanical stop 502) overlaps with the central stage 220 in a first direction (e.g., vertical direction). As shown, the protrusion (mechanical stop 502) is formed from the base (base wafer 700). However, the first protrusion (mechanical stop 502) may be formed from a separate layer on the base (base wafer 700). As show, the central stage 220 includes a bottom portion facing the first protrusion (mechanical stop 502). The first protrusion (mechanical stop 502) is spaced apart from the bottom portion of the central stage 220 by a predetermined distance (e.g., distance between 3 μm and 15 μm).

As shown, the mirror array 800 also includes a second protrusion (mechanical stop 1012) on the lid (lid wafer 802), and a third protrusion (mechanical stop 1012) on the lid (lid wafer 802). The second protrusion (mechanical stop 1012) and the third protrusion (mechanical stop 1012) extend towards the base (base wafer 700). As shown, the mirror array 800 also includes a first stationary frame flexure (mirror's flexure 152) and a second stationary frame flexure (mirror's flexure 154). The first stationary frame flexure (mirror's flexure 152) and the second stationary frame flexure (mirror's flexure 154) suspend the movable frame 227 from the stationary frame 214. As shown, the second protrusion (mechanical stop 1012) overlaps with the first stationary frame flexure (mirror's flexure 152) in the first direction, and the third protrusion (mechanical stop 1012) overlaps with the second stationary frame flexure (mirror's flexure 154) in the first direction. As shown, the second protrusion (mechanical stop 1012) is apart from the first stationary frame flexure (mirror's flexure 152) by a predetermined distance (e.g., distance between 3 μm and 15 μm). As shown, the third protrusion (mechanical stop 1012) is apart from the second stationary frame flexure (mirror's flexure 154) by a predetermined distance (e.g., distance between 3 μm and 15 μm). As shown, the second protrusion (mechanical stop 1012) and the third protrusion (mechanical stop 1012) are non-overlapped with the central stage 220 in the first direction.

As shown, the mirror array 800 also includes a fourth protrusion (support anchor 430) and a fifth protrusion (support anchor 430) on the base (base wafer 700). As shown, the fourth protrusion (support anchor 430) and the fifth protrusion (support anchor 430) are formed from the base (base wafer 700). However, the fourth protrusion (support anchor 430) and the fifth protrusion (support anchor 430) may be formed from a (separate) layer on the base (base wafer 700). As shown, the first protrusion (support anchor 430) is between the fourth protrusion (support anchor 430) and the fifth protrusion (support anchor 430). As shown, the fourth protrusion (support anchor 430) is configured to support a first support member (support webbing 234), and the fifth protrusion (support anchor 430) is configured to support a second support member (support webbing 234). As shown, the central stage 220 includes a bottom portion extending towards the first protrusion (mechanical stop 502). As shown, the bottom portion of the central stage 220 is between the first support member (support webbing 234) and the second support member (support webbing 234).

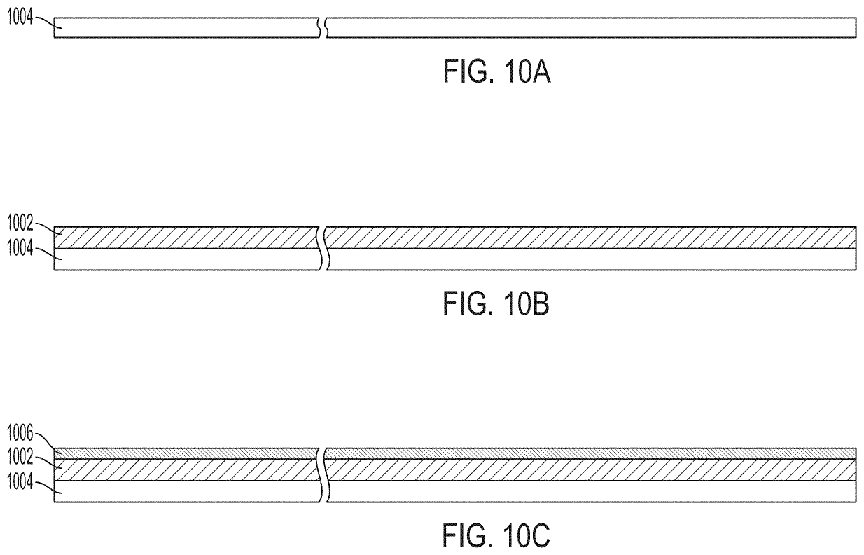

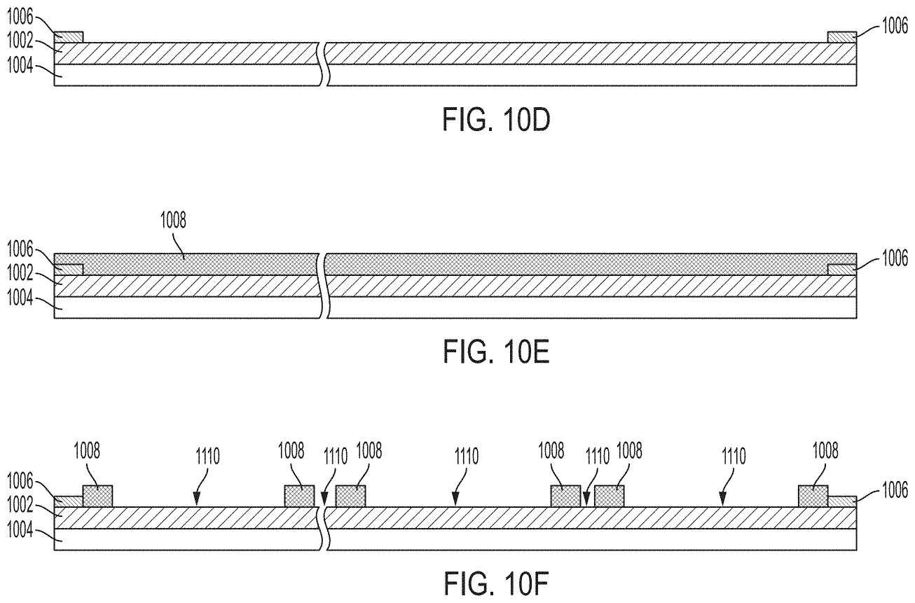

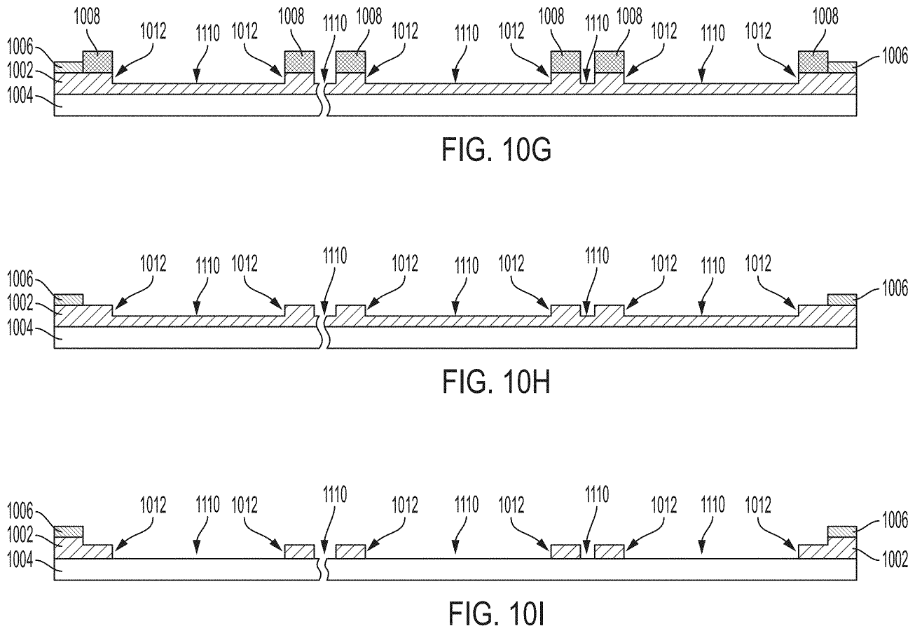

FIGS. 10A-I illustrates a manufacturing process for fabricating the lid wafer 802 (also referred as lid). A glass wafer 1004 (lid wafer 802 in FIG. 8) as shown in FIG. 10A is provided. A silicon wafer 1002 (also referred as silicon substrate) is then fusion bonded to the glass wafer 1004 as shown in FIG. 10B. A hard mask material 1006 (also referred as hard mask layer) is then deposited on the silicon wafer 1002. This material can be silicon dioxide, silicon nitride, aluminum, or another material that can serve as a mask for deep reactive ion etching of silicon. The material can also serve as the bonding material later in the process.

FIG. 10D illustrates the hard mask material 1006 patterned to allow for the etching of a cavity below the movable mirrors 100. The patterning is done using standard photolithography and etching methods. Turning to FIG. 10E, a coating of photoresist 1008 (also referred as photoresist layer) is deposited on the silicon wafer 1002 and the hard mask material 1006. The photoresist 1008 is patterned to define the locations of the mechanical stop 1012 as shown in FIG. 10F. Deep reactive ion etching is used to partially etch into the silicon wafer 1002 as shown in FIG. 10G. The depth of this etch can be determined by thickness of the silicon wafer 1002 minus the gap desired between each of the mechanical stops 1012 and the top of a corresponding mirror flexure 152, 154. As discussed above, for example, the desired gap distance is between 3 μm and 15 μm, approximately. The photoresist 1008 is stripped from the silicon wafer 1002 in FIG. 10H. Deep reactive ion etching is then used once again, as shown in FIG. 10I, to complete the etching of the cavity to the final desired depth which clears the silicon and exposes the glass wafer surface 1110. As shown in FIG. 10I, during the deep reactive ion etching process, top surfaces of the mechanical stops 1012 are also etched. Accordingly, the height for each of the mechanical stops 1012 is adjusted to a final desired height. At a result, the gap is formed between each of the mechanical stops 1012 and the corresponding minor flexure 152, 154 as shown in FIGS. 8 and 9. The hard mask material 1006 can remain on the silicon wafer 1002 or be removed, depending on the bonding technique. As shown in FIG. 10I, the entire structure is lid wafer 802.

As shown in FIGS. 7A-H, 8, 9, and 10A-10I, another aspect of the disclosure provides a fabrication method of the minor array 800. In particular, the disclosure provides a fabrication method of the lid (lid wafer 802) as well as a fabrication method of a base (base wafer 700). As shown in FIG. 8, the minor array 800 includes a plurality of movable minors 100 that are spaced apart from each other. As discussed, each of the plurality of movable mirrors 100 may include a stationary frame 214 including a cavity 232, a movable frame 227 in the cavity 232, and a central stage 220 in the cavity 232. As shown, the movable frame 227 is suspended from the stationary frame 214 by a first stationary frame flexure 152 and a second stationary frame flexure 154. As shown in FIGS. 8, 9, and 10A-10I, the lid (lid wafer 802) may be formed separately from the plurality of movable mirrors 100 and the base (base wafer 700). After forming the lid (lid wafer 802) as shown in FIGS. 10A-10I, the lid (lid wafer 802) can be placed on the plurality of movable mirrors 100. In some circumstances, the plurality of movable mirrors 100 is placed under the lid (lid wafer 802). As shown, when the lid (lid wafer 802) is covering the plurality of movable mirrors 100, each of the protrusions (mechanical stops 1012) on the lid (lid wafer 802) overlaps with one of the stationary frame flexures 152, 154 in a first direction (e.g., vertical direction). As shown in FIGS. 7A-7H, 8, 9, and 10A-10I, the base (base wafer 700) may be formed separately from the plurality of movable mirrors 100 and the lid (lid wafer 802). After forming the base (base wafer 700) as shown in FIGS. 7A-7H, the base (base wafer 700) can be placed under the plurality of movable mirrors 100. In some circumstances, the plurality of movable mirrors 100 is placed on the base (base wafer 700). As shown, the base (base wafer 700) includes a plurality of protrusions (mechanical stops 502, support anchors 430). As shown, when the base (base wafer 700) is supporting the plurality of movable mirrors 100, some of protrusions (mechanical stops 502) on the base (base wafer 700) overlap with central stages 220 in the first direction and some of the protrusions (support anchors 430) on the base (base wafer 700) overlap with support webbings 234 of the plurality of movable mirrors in the first direction. In a broad view, as shown in FIG. 8, the mirror array 800 can be fabricated by bonding the base (base wafer 700) to the device wafer 220′ (including the plurality of movable mirrors 100) and bonding the device wafer 220′ to the lid (lid wafer 802).

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the claims define the scope of the invention and that methods and structures within the scope of these claims and their equivalents be covered thereby.

What is claimed:

1. A mirror array, comprising:
a lid;
a base;
a movable mirror between the lid and the base, the movable mirror including:
a stationary frame including a cavity;
a movable frame in the cavity;
a central stage in the cavity; and
a first protrusion on the base, wherein the first protrusion overlaps with the central stage in a first direction.

2. The mirror array of claim 1, wherein the central stage includes a bottom portion facing the first protrusion.

3. The mirror array of claim 2, wherein the first protrusion is spaced apart from the bottom portion of the central stage by a predetermined distance.

4. The mirror array of claim 3, wherein the predetermined distance is between 3 μm and 15 μm.

5. The mirror array of claim 1, further comprising:
a second protrusion on the lid; and
a third protrusion on the lid, wherein the second protrusion and the third protrusion extend towards the base.

6. The mirror array of claim 5, further comprising:
a first stationary frame flexure;
a second stationary frame flexure, wherein the first stationary frame flexure and the second stationary frame flexure suspend the movable frame from the stationary frame.

7. The mirror array of claim 6, wherein the second protrusion overlaps with the first stationary frame flexure in the first direction, and wherein the third protrusion overlaps with the second stationary frame flexure in the first direction.

8. The mirror array of claim 6, wherein the second protrusion is apart from the first stationary frame flexure by a predetermined distance.

9. The mirror array of claim 8, wherein the predetermined distance is between 3 μm and 15 μm.

10. The mirror array of claim 6, wherein the third protrusion is apart from the second stationary frame flexure by a predetermined distance.

11. The mirror array of claim 10, wherein the predetermined distance is between 3 μm and 15 μm.

12. The mirror array of claim 5, wherein the second protrusion and the third protrusion are non-overlapped with the central stage in the first direction.

13. The mirror array of claim 1, further comprising:
a fourth protrusion on the base; and
a fifth protrusion on the base,
wherein the first protrusion is between the fourth protrusion and the fifth protrusion.

14. The mirror array of claim 13, wherein the fourth protrusion is configured to support a first support member, and wherein the fifth protrusion is configured to support a second support member.

15. The mirror array of claim 14, wherein the central stage includes a bottom portion extending towards the first protrusion, and wherein the bottom portion is between the first support member and the second support member.

16. A mirror array, comprising:
a movable mirror, the movable mirror including:
a stationary frame including a cavity;
a movable frame in the cavity, the movable frame suspended from the stationary frame by a first stationary frame flexure and a second stationary frame flexure;
a central stage in the cavity; and
a lid wafer covering the movable mirror;
a first protrusion on the lid wafer, the first protrusion extended towards the movable mirror.

17. The mirror array of claim 16, wherein the first protrusion overlaps with the first stationary frame flexure in a first direction.

18. The mirror array of claim 16, wherein a gap between the first protrusion and the first stationary frame flexure is between 3 μm and 15 μm.

19. The mirror array of claim 16, further comprising a second protrusion on the lid wafer, wherein the second protrusion overlaps with the second stationary frame flexure in a first direction.

20. The mirror array of claim 19, wherein a gap between the second protrusion and the second stationary frame flexure is between 3 μm and 15 μm.

21. The mirror array of claim 16, further comprising:
a base wafer; and
a third protrusion on the base wafer, wherein the third protrusion overlaps with the central stage in a first direction.

22. The mirror array of claim 21, wherein the third protrusion is spaced apart from a bottom portion of the central stage by a predetermined distance.

23. The mirror array of claim 22, wherein the predetermined distance is between 3 μm and 15 μm.

24. A fabrication method of mirror array, the method comprising:
forming a plurality of movable mirrors that are spaced apart from each other, the plurality of movable mirrors including a first movable mirror, the first movable mirror including:
a stationary frame including a cavity;
a movable frame in the cavity, the movable frame suspended from the stationary frame by a first stationary frame flexure and a second stationary frame flexure; and
a central stage in the cavity;
forming a lid, the lid having a plurality of protrusions, the plurality of protrusions including a first protrusion and a second protrusion;
covering the plurality of movable mirrors with the lid so that the first protrusion overlaps with the first stationary frame flexure in a first direction, and the second protrusion overlaps with the second stationary frame flexure in the first direction;
forming a base, the base having a plurality of base protrusions, the plurality of base protrusions including a first base protrusion,
supporting the plurality of movable mirrors with the base so that the first base protrusion overlaps with the central stage in the first direction.

25. The fabrication method of mirror array of claim 24, wherein forming the lid includes:
bonding a silicon wafer to a glass wafer;
disposing a hard mask layer on the silicon wafer;
patterning the hard mask layer;
disposing a photoresist layer on the patterned hard mask layer and the silicon wafer;
patterning the photoresist layer to define locations of the plurality of protrusions; and
etching the silicon wafer that is exposed;

26. The fabrication method of mirror array of claim 25, further comprising:
removing the patterned photoresist layer; and
etching the silicon wafer that is exposed after removing the patterned photoresist layer.

27. The fabrication method of mirror array of claim 24, wherein forming the base includes:
disposing a hard mask layer on a base wafer;
patterning the hard mask layer;
disposing a photoresist layer on the patterned hard mask layer and the base wafer;
patterning the photoresist layer to define locations of the plurality of base protrusions; and
etching the base wafer that is exposed.

28. The fabrication method of mirror array of claim 27, further comprising:
removing the patterned photoresist layer; and
etching the base wafer that is exposed after moving the patterned photoresist layer.
